(19) United States
(12) Patent Application Publication
(10) Pub. No.: US 2025/0107168 A1
(43) Pub. Date: Mar. 27, 2025

(54) SEMICONDUCTOR DEVICE

(71) Applicant: FUJI ELECTRIC CO., LTD., Kawasaki-shi (JP)

(72) Inventor: Yasuyuki HOSHI, Matsumoto-city (JP)

(73) Assignee: FUJI ELECTRIC CO., LTD., Kawasaki-shi (JP)

(21) Appl. No.: 18/790,482

(22) Filed: Jul. 31, 2024

(30) Foreign Application Priority Data
Sep. 26, 2023 (JP) 2023-164012

(51) Int. Cl. H01L 29/06; H01L 29/16; H01L 29/78

(52) U.S. Cl. CPC H10D 62/109; H10D 30/665; H10D 30/668; H10D 62/8325

(57) ABSTRACT

A semiconductor device, including: a semiconductor substrate containing silicon carbide, the semiconductor substrate having a first main surface and a second main surface opposite to each other; an n-type region provided in the semiconductor substrate; a p-type region provided in the semiconductor substrate, between the first main surface of the semiconductor substrate and n-type region, the p-type region being in contact with the n-type region; a first electrode electrically connected to the p-type region; and a second electrode electrically connected to the n-type region. At least one portion of the p-type region is a p-type polysilicon portion.

### CROSS REFERENCE TO RELATED APPLICATIONS

This application is based upon and claims the benefit of priority of the prior Japanese Patent Application No. 2023-164012, filed on Sep. 26, 2023, the entire contents of which are incorporated herein by reference.

### BACKGROUND OF THE INVENTION

### 1. Field of the Invention

Embodiments of the disclosure relate to a semiconductor device.

### 2. Description of the Related Art

Japanese Laid-Open Patent Publication No. 2020-120072 describes use of aluminum (Al) as a p-type dopant in the formation of a p-type silicon carbide (SiC) region by an ion implantation method, an epitaxial growth method, etc., in a metal oxide semiconductor field effect transistor (MOSFET) having an insulated gate with a three-layer metal-oxide-semiconductor structure in which SiC is used as a semiconductor material (SiC-MOSFET).

### SUMMARY OF THE INVENTION

According to an embodiment of the present disclosure, a semiconductor device includes: a semiconductor substrate containing silicon carbide, the semiconductor substrate having a first main surface and a second main surface opposite to each other; an n-type region provided in the semiconductor substrate; a p-type region provided in the semiconductor substrate, between the first main surface of the semiconductor substrate and n-type region, the p-type region being in contact with the n-type region; a first electrode electrically connected to the p-type region; and a second electrode electrically connected to the n-type region. At least one portion of the p-type region is a p-type polysilicon portion.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a semiconductor device according to a first embodiment is viewed from a front side of a semiconductor substrate thereof.

FIG. 2 is a cross-sectional view depicting the structure along cutting line A-A′ in FIG. 1.

FIG. 3 is a cross-sectional view depicting another example of the structure along cutting line A-A′ in FIG. 1.

FIG. 4 is a cross-sectional view depicting a structure of a semiconductor device according to a second embodiment.

FIG. 5 is a cross-sectional view depicting a structure of a semiconductor device according to a third embodiment.

FIG. 6 is a cross-sectional view depicting a structure of a semiconductor device according to a fourth embodiment.

FIG. 7 is a characteristics diagram showing a relationship between sheet resistance of p-type SiC regions of a semiconductor device of a reference example and temperature of a semiconductor substrate 120.

FIG. 8 is a cross-sectional view depicting a structure of the semiconductor device of the reference example.

### DETAILED DESCRIPTION OF THE INVENTION

First, problems associated with the conventional technique are discussed. A band gap of SiC is relatively large and thus, at a low temperature of about-40 degrees C. or about-55 degrees C., sheet resistance of a p-type SiC region formed with Al as a p-type dopant increases. Thus, spreading of a depletion layer in the p-type SiC region is facilitated, majority carriers in the p-type SiC region are depleted, the depletion layer easily reaches a vicinity near the surface of the device element, whereby high electric field is locally applied to the device element structure and there is a risk of destruction.

An overview of an embodiment of the present disclosure is described.

(1) A semiconductor device according to one aspect of the present disclosure is as follows. In a semiconductor substrate containing silicon carbide, an n-type region is provided. A p-type region is provided in the semiconductor substrate, between the first main surface of the semiconductor substrate and the n-type region. A first electrode is electrically connected to the p-type region. A second electrode is electrically connected to the n-type region. At least one portion of the p-type region is a p-type polysilicon portion.

According to the disclosure above, even with a low temperature, the carrier concentration of the p-type polysilicon portion does not decrease and thus, spreading of a depletion layer in the p-type region is difficult and majority carriers in the p-type region are not depleted. As a result, the depletion layer does not easily reach a vicinity of the first main surface of the semiconductor substrate and local electric field concentration may be suppressed. As a result, switching capability, particularly, tolerance against steep dV/dt may be enhanced.

(2) Further, in the semiconductor device according to the present disclosure, in (1) described above, a remaining portion of the p-type region excluding the p-type polysilicon portion is a p-type silicon carbide portion.

According to the disclosure above, in the p-type region, effects based on material properties of silicon carbide may also be obtained.

(3) Further, in the semiconductor device according to the present disclosure, in (1) described above, the p-type region may be entirely constituted by the p-type polysilicon portion.

According to the disclosure above, for example, the p-type polysilicon portion may be easily formed by merely depositing the p-type polysilicon layer at an uppermost surface of the semiconductor substrate.

(4) Further, the semiconductor device according to the present disclosure, in (1) or (2) described above, further includes a plurality of n-type partial regions selectively provided in the semiconductor substrate, between the first main surface of the semiconductor substrate and the p-type region, each of the plurality of n-type partial regions being entirely constituted by an n-type silicon carbide portion.

According to the disclosure above, in the n-type region, effects based on material properties of silicon carbide may be maintained.

(5) Further, the semiconductor device according to the present disclosure, in (2) described above, further includes a plurality of n-type partial regions selectively provided in the semiconductor substrate, between the first main surface of the semiconductor substrate and the p-type region, and a portion of each of the plurality of n-type partial regions may be an n-type polysilicon portion. A remaining portion of each of the plurality of n-type partial regions excluding the n-type polysilicon portion is an n-type silicon carbide portion. The n-type polysilicon portion is selectively provided in the p-type polysilicon portion. The n-type silicon carbide portion is selectively provided in the p-type silicon carbide portion.

According to the disclosure above, in the configuration in which a portion of the p-type region is the p-type polysilicon portion, the plurality of n-type partial regions (the n-type polysilicon portion and the n-type silicon carbide portion) may be easily formed by only ion-implantation of an n-type dopant.

(6) Further, the semiconductor device according to the present disclosure, in (3) described above, further includes a plurality of n-type partial regions selectively provided in the semiconductor substrate, between the first main surface of the semiconductor substrate and the p-type region, and each of the plurality of n-type partial regions may be entirely constituted by an n-type polysilicon portion.

According to the disclosure above, in the configuration in which the p-type region is entirely constituted by the p-type polysilicon portion, the plurality of n-type partial regions (n-type polysilicon portion) may be easily formed by only ion-implantation of an n-type dopant.

(7) Further, in the semiconductor device according to the present disclosure, in any one of (1) to (6) described above, a predetermined device element structure including a pn junction between the p-type region and the n-type region is provided in an active region of the semiconductor substrate. The first electrode is provided at the first main surface of the semiconductor substrate and is electrically connected to the device element structure. The second electrode is provided at the second main surface of the semiconductor substrate.

According to the disclosure above, a vertical semiconductor device is applicable, in which current passes through the pn junction, in a vertical direction, between the first and second main surfaces of the semiconductor substrate.

(8) Further, the semiconductor device according to the present disclosure, in (7) described above, may include a termination region in which a predetermined voltage withstanding structure is disposed, the termination region surrounding a periphery of the active region; and the p-type region may be a plurality of p-type regions provided in the semiconductor substrate. The plurality of p-type regions may include a first p-type base region provided in the active region and configuring the device element structure. The plurality of p-type regions may include a second p-type region provided in the termination region and configuring the voltage withstanding structure.

According to the disclosure above, in the termination region, the dielectric breakdown of an insulating layer covering the first main surface of the semiconductor substrate may be suppressed.

(9) Further, the semiconductor device according to the present disclosure, in (8) described above, further includes a boundary region between the active region and the termination region; and a wiring layer provided in the boundary region, on the first main surface of the semiconductor substrate via the insulating layer. The plurality of p-type regions may include a third p-type region electrically connected to the first electrode and provided in the boundary region so as to face the wiring layer in a depth direction via the insulating layer.

According to the disclosure above, in the boundary region, dielectric breakdown of the insulating layer covering the first main surface of the semiconductor substrate may be suppressed.

(10) Further, in the semiconductor device according to the present disclosure, in any one of (1) to (9) described above, aluminum or boron may be introduced as a p-type dopant into the p-type polysilicon portion.

According to the disclosure above, the p-type polysilicon portion may be formed by an existing method of manufacturing a semiconductor device, using a general p-type dopant.

(11) Further, in the semiconductor device according to the present disclosure, in any one of (5) to (7) described above, phosphorus, arsenic, or nitrogen may be introduced as an n-type dopant into the n-type polysilicon portion.

According to the disclosure above, the n-type polysilicon portion may be formed by an existing method of manufacturing a semiconductor device, using a general n-type dopant.

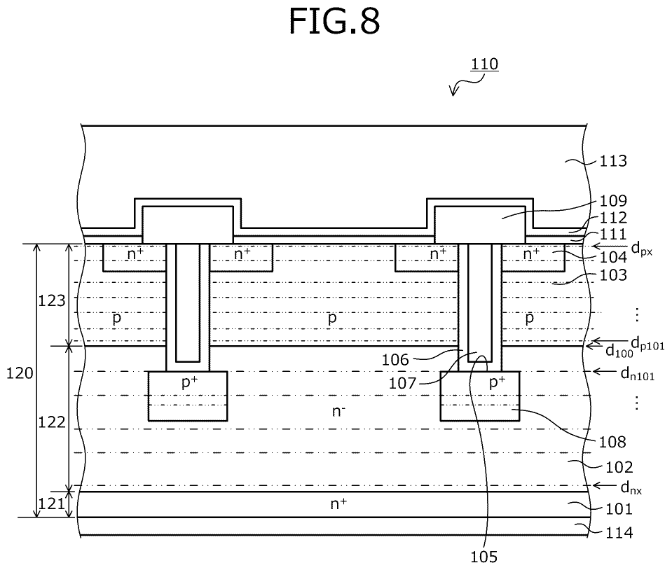

Findings underlying the present disclosure are discussed. Problems associated with a semiconductor device of a reference example are discussed. FIG. 8 is a cross-sectional view depicting a structure of a semiconductor device of the reference example. A semiconductor device 110 of the reference example depicted in FIG. 8 is a vertical SiC-MOSFET having a trench gate structure in an active region of a semiconductor substrate (semiconductor chip) 120 containing silicon carbide (SiC) as a semiconductor material. In the semiconductor substrate 120, on an n⁺-type starting substrate 121 containing SiC as a semiconductor material, SiC layers 122, 123 constituting an n-type drift region 102 and a p-type base region 103 are sequentially grown by epitaxy in the order stated.

The n⁺-type starting substrate 121 constitutes an n⁺-type drain region 101. The semiconductor substrate 120 has, as a front surface, a main surface having the p-type SiC layer 123 and has, as a back surface, a main surface having the n⁺-type starting substrate 121. The trench gate structure is configured by the p-type base region 103, n⁺-type source regions 104, p⁺⁺-type contact regions (not depicted), gate trenches 105, gate insulating films 106, and gate electrodes 107, between the front surface of the semiconductor substrate 120 and the n-type drift region 102. p⁺-type regions 108 are provided facing bottoms of the gate trenches 105.

The p-type base region 103 is a portion of the p-type SiC layer 123 excluding the n⁺-type source regions 104 and the p⁺⁺-type contact regions; the p-type base region 103 is provided between the front surface of the semiconductor substrate 120 and the n-type drift region 102. The n⁺-type source regions 104 and the p⁺⁺-type contact regions are each selectively provided between the front surface of the semiconductor substrate 120 and the p-type base region 103. The n⁺-type source regions 104 and the p⁺⁺-type contact regions are diffused regions (SiC portions) formed by ion implantation in surface regions of the p-type SiC layer 123.

The gate trenches 105 penetrate through the n⁺-type source regions 104 and the p-type base region 103 and terminate in the n-type drift region 102. In the gate trenches 105, the gate electrodes 107 are provided via the gate insulating films 106. The p⁺-type regions 108 are diffused regions formed by ion implantation in the n-type SiC layer 122. In the formation of the p-type base region 103, the p⁺⁺-type contact regions, and the p⁺-type regions 108, aluminum (Al) is used as a p-type dopant.

An interlayer insulating film 109 is provided in an entire area of the front surface of the semiconductor substrate 120 and covers the gate electrodes 107. In contact holes of the interlayer insulating film 109, a source electrode 113 is electrically connected to the p-type base region 103, the n⁺-type source regions 104, and the p⁺⁺-type contact regions, via a barrier metal 112 and ohmic electrodes 111. In an entire area of the back surface (back surface of the n⁺-type starting substrate 121) of the semiconductor substrate 120, a drain electrode 114 is provided in contact with the n⁺-type starting substrate 121 (the n⁺-type drain region 101).

As described, in the semiconductor device 110 of the reference example, Al is used as a p-type dopant in the formation of the p-type base region 103, the p⁺⁺-type contact regions constituting electrical contacts with the ohmic electrodes 111, and p-type SiC regions such as the p⁺-type regions 108 for mitigating electric field. While not depicted, p-type SiC regions configuring a voltage withstanding structure disposed in an edge termination region surrounding a periphery of the active region, and p-type SiC regions disposed in a boundary region (not depicted) between the active region and the edge termination region are also formed by ion implantation with Al as a p-type dopant.

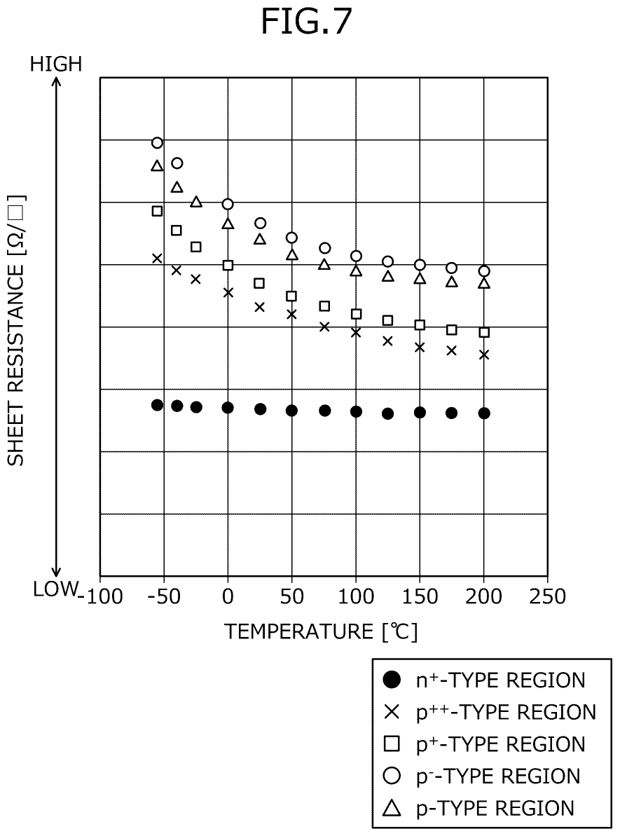

Diligent research of the present inventor confirmed that as described, when Al is used as a p-type dopant to form p-type SiC regions, the sheet resistance of the p-type SiC regions increases the lower is the junction temperature (temperature of the semiconductor substrate 120). As for the semiconductor device 110 of the reference example, sheet resistance measurements [ohm per square (Ω/□)] obtained for an n-type SiC region and multiple p-type SiC regions of differing doping concentration, by variously changing the temperature of the semiconductor substrate 120 are shown in FIG. 7. FIG. 7 is a characteristics diagram showing a relationship between the sheet resistance of the p-type SiC regions of the semiconductor device of the reference example and the temperature of the semiconductor substrate 120.

In FIG. 7, an n⁺-type region, a p⁺⁺-type region, a p⁺-type region, and a p-type region correspond to, respectively, the n⁺-type source regions 104, the p⁺⁺-type contact regions, the p⁺-type regions 108, and the p-type base region 103 in FIG. 8. In FIG. 7, a p-type region corresponds to a p-type SiC region that configures a voltage withstanding structure such as a field limiting ring (FLR), a junction termination extension (JTE) structure, etc. disposed in the edge termination region (not depicted) of the semiconductor device 110 of the reference example.

From the results shown in FIG. 7, it was confirmed that even when the temperature of the semiconductor substrate 120 changes, the sheet resistance of the n-type SiC region (n⁺-type region) is nearly unchanged while for the p-type SiC regions (the p⁺⁺-type region, the p⁺-type region, the p-type region, and the p-type region), the sheet resistance increases the lower is the temperature of the semiconductor substrate 120 and exhibits a same tendency independent of the doping concentration. Thus, it may be said that the sheet resistance of all the p-type SiC regions formed in the semiconductor substrate 120 with Al as a p-type dopant exhibits the same tendency as the p-type SiC regions in FIG. 7 with respect to the temperature of the semiconductor substrate 120.

When the sheet resistance of the p-type SiC regions becomes high due to the temperature of the semiconductor substrate being a low temperature, a depletion layer of a width greater than a design width spreads in the p-type SiC region, from pn junctions between the p-type SiC region and the n-type SiC region. The steeper is the change in the dV/dt (rate of change over time of drain-source voltage) when the SiC-MOSFET is off, the more a depletion layer transiently spreads in the p-type SiC region, whereby majority carriers (holes) in the p-type SiC region become depleted and the p-type SiC region tends to stop functioning as a stopper to stop the spreading of the depletion layer.

For example, normally, the active region is designed so that when the SiC-MOSFET is off, a depletion layer that spreads in the p-type base region 103, from pn junctions between the p-type base region 103 and the n-type drift region 102, does not reach the n⁺-type source regions 104. However, when the sheet resistance of the p-type base region 103 increases due to the temperature of the semiconductor substrate 120 becoming a low temperature, the carrier concentration (concentration of the activated dopant) of the p-type base region 103 becomes lower than a design value and thus, the depletion layer spreads in a vertical direction in the p-type base region 103 sooner than usual so that the potential difference (diffusion potential) at both ends (end in the p-type base region 103 and end in the n-type drift region 102) becomes balanced.

At this time, when the SiC-MOSFET is rapidly turned off and dV/dt is steeply varied, the depletion layer that spreads in the p-type base region 103 reaches the n⁺-type source regions 104 and punches through in a short period, whereby local device element destruction may occur. In FIG. 8, short-dash two-dot chains and long-dash two-dot chains conceptually represent depth positions dₚₓ, dₙₓ (where, “x” is a positive number greater than or equal to 101: in other words, equipotential line distribution of the depletion layer in the p-type base region 103 and the n-type drift region 102) corresponding to the diffusion potential of both ends (end in the p-type base region 103 and end in the n-type drift region 102) of the diffusion layer, which spreads vertically in both directions to both main surfaces of the semiconductor substrate 120, from the pn junctions between the p-type base region 103 and the n-type drift region 102, when the SiC-MOSFET is off.

The higher is the voltage applied to the pn junctions between the p-type base region 103 and the n⁻-type drift region 102, the closer the depletion layer reaches the depth positions dₚₓ, dₙₓ, which are apart from a depth position d₁₀₀ of the pn junctions. FIG. 8 depicts an example in which an interval (potential difference between dash two-dot chains) of equipotential lines of the depletion layer in the p-type base region 103 and the n⁻-type drift region 102 is assumed to be 100V and when the voltage applied to the pn junctions between the p-type base region 103 and the n⁻-type drift region 102 becomes 600V or greater, ends (equipotential lines of sixth and seventh depth positions dₚ₁₀₆, dₚ₁₀₇ from the depth position d₁₀₀ of the pn junctions) of the depletion layer that spreads in a vertical direction in the p-type base region 103 reach the n⁺-type source regions 104.

Even in an instance in which only p-type SiC regions are disposed between the front surface of the semiconductor substrate 120 and the n⁻-type drift region 102, when the temperature of the semiconductor substrate 120 is a low temperature, the depletion layer that spreads in the p-type SiC region, from the pn junctions between the p-type SiC region and the n⁻-type drift region 102 due to the steep dV/dt when the SiC-MOSFET turns off reaches the insulating layer on the front surface of the semiconductor substrate 120, electric field concentrates there and dielectric breakdown occurs. While not depicted, also in an instance in which a p-type SiC region is formed with boron (B) as a p-type dopant, the sheet resistance of the p-type SiC regions is presumed to exhibit the same tendency with respect to the temperature of the semiconductor substrate as the tendency exhibited by the p-type SiC regions in FIG. 7.

Thus, in the present embodiments, enhancing switching capability of the SiC-MOSFET (semiconductor device) independent of the temperature of the semiconductor substrate, particularly, enhancing tolerance against steep dV/dt is one problem to be solved. Switching capability indicates tolerance against dynamic destruction due to short-circuit, turn-on, turn-off, dV/dt, etc.

Embodiments of a semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

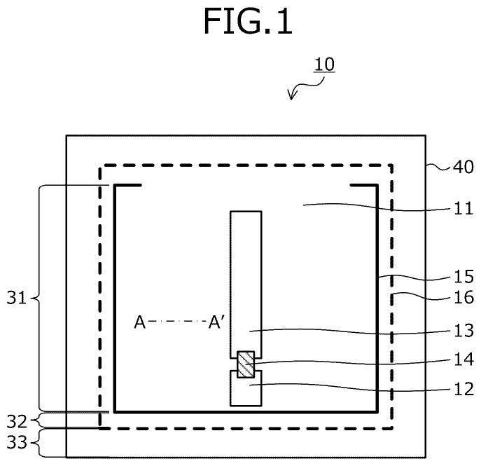

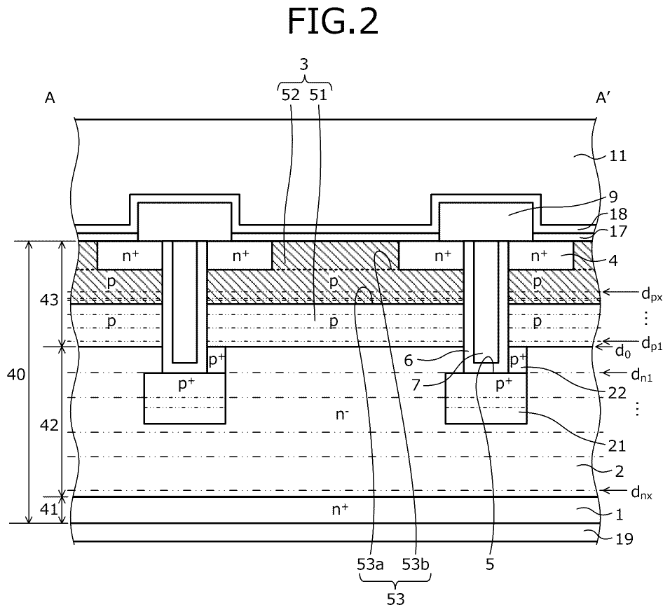

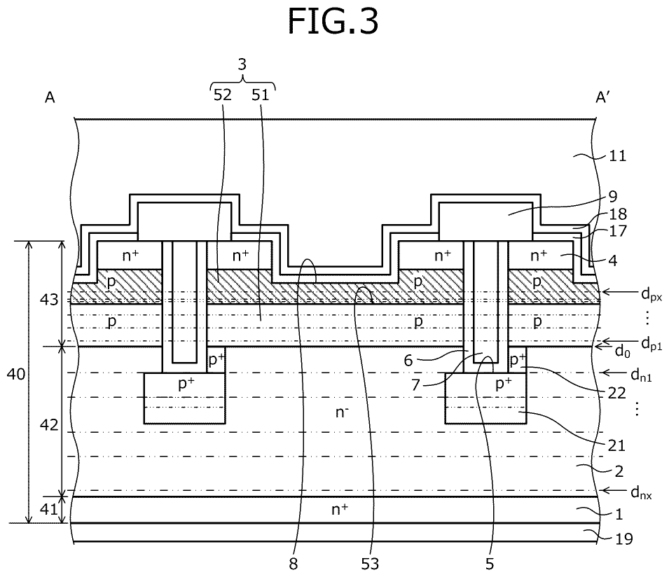

A semiconductor device according to a first embodiment solving the problems above is described. FIG. 1 is a plan view depicting a layout when the semiconductor device according to the first embodiment is viewed from a front side of a semiconductor substrate thereof. FIG. 2 is a cross-sectional view depicting the structure along cutting line A-A′ in FIG. 1. FIG. 3 is a cross-sectional view depicting another example of the structure along cutting line A-A′ in FIG. 1. In FIGS. 1 and 2, a semiconductor device 10 according to the first embodiment is a vertical SiC-MOSFET having a trench gate structure (device element structure) in an active region 31 of a semiconductor substrate (semiconductor chip) 40 containing silicon carbide (SiC) as a semiconductor material.

The active region 31 is a region through which a main current (drift current) passes when the MOSFET is on. The active region 31, for example, has a substantially rectangular shape in a plan view of the device and is disposed in substantially a center (chip center) of the semiconductor substrate 40. The active region 31 has an operating region in which multiple cells (functional units of a device element) each having a same MOSFET structure are disposed adjacent to one another; the operating region occupies a majority of the area of the semiconductor substrate 40. The active region 31 has a non-operating region that is a region of the active region 31 excluding the operating region; the non-operating region is free of MOSFET cells and does not function as the MOSFET.

A boundary region 32 between the active region 31 and an edge termination region 33 surrounds a periphery of the active region 31 in a substantially rectangular shape. In the boundary region 32, a p-type outer peripheral region (not depicted) for drawing out holes in an n-type drift region 2 to a source electrode 11 when the MOSFET is off is provided in an entire area between a front surface of the semiconductor substrate 40 and the n-type drift region 2. The edge termination region 33 is a region between the boundary region 32 and an end (chip end) of the semiconductor substrate 40; the edge termination region 33 surrounds a periphery of the boundary region 32 in a substantially rectangular shape. In the edge termination region 33, a predetermined voltage withstanding structure is disposed.

On the front surface of the semiconductor substrate 40, an electrode pad such as a source pad (the source electrode 11) and a gate pad 12, a metal wiring layer such as a gate runner 13, a gate ring 15 (solid thick line in FIG. 1) and a source ring 16 (dashed line in FIG. 1), a gate resistor 14 (hatched portion in FIG. 1) containing polysilicon (poly-Si), and a gate polysilicon wiring layer (not depicted) are provided. The source electrode (first electrode) 11 is provided in the operating region of the active region 31 and covers substantially an entire surface of the operating region of the active region 31.

The gate pad 12, the gate runner 13, the gate resistor 14, and the gate polysilicon wiring layer directly beneath (side facing an n⁺-type drain region 1) the gate pad 12 and the gate runner 13 are provided in the non-operating region of the active region 31. The gate ring 15, the source ring 16, and the gate polysilicon wiring layer directly beneath the gate ring 15 are provided in the boundary region 32. Gate electrodes 7 of all the cells of the MOSFET are electrically connected to the gate pad 12 via the gate resistor 14 and the gate runner 13.

The gate ring 15, for example, has an open portion of a substantially rectangular shape and thereby surrounds the periphery of the active region 31. The gate ring 15, at a location apart from the gate runner 13, is electrically connected to the gate electrodes 7 via the gate polysilicon wiring layer directly beneath the gate ring 15 and has a function of making potential of the gate electrodes 7 all the cells uniform. The source ring 16 is disposed closer to the chip end than is the gate ring 15 and surrounds the periphery of the active region 31 in a substantially rectangular shape. The source ring 16 is connected to the source electrode 11 by the opened portion of the gate ring 15 and is fixed to the potential of the source electrode 11.

In the semiconductor substrate 40, on a front surface of an n⁺-type starting substrate 41 containing SiC as a semiconductor material, SiC layers 42, 43 constituting the n-type drift region (n-type region) 2 and a p-type base region (p-type region, first p-type base region) 3 are grown by epitaxy. Other than epitaxial growth, the p-type base region 3 may be formed by ion-implantation of aluminum (Al) in the n-type drift region 2. The semiconductor substrate 40 has, as the front surface, a first main surface having the p-type SiC layer 43 and has, as a back surface, a second main surface having the n⁺-type starting substrate 41. The n⁺-type starting substrate 41 constitutes the n⁺-type drain region 1. In the n-type SiC layer 42, for example, phosphorus (P) or arsenic (As) is doped as an n-type dopant.

In the p-type SiC layer 43, for example, aluminum (Al) or boron (B) is doped as a p-type dopant. In the semiconductor substrate 40, p-type regions include the p-type SiC layer 43 itself or a p-type SiC portion (in FIG. 2, corresponds to a p-type SiC portion 51) configured by a diffused region (SiC portion in which a dopant of a predetermined conductivity type is diffused) formed by ion implantation in the SiC layers 42, 43, and a p-type polysilicon portion (in FIG. 2, corresponds to a p-type polysilicon portions 52) formed by a p-type polysilicon with, for example, Al or B as a p-type dopant.

The n-type SiC layer 42 may be formed by multi-stage epitaxial growth and divided into two sublayers including a first sublayer from an interface with the n⁺-type starting substrate 41 to upper surfaces (respective surfaces facing n⁺-type source regions 4) of later described p⁺-type regions 21 and a second sublayer (portion where later-described p⁺-type connecting portions 22 are provided) from respective upper surfaces of the p⁺-type regions 21 to an interface with the p-type SiC layer 43. A thickness of the second sublayer (portion where the later-described p⁺-type connecting portions 22 are provided) of the n-type SiC layer 42 is, for example, about 0.5 μm. A thickness of the p-type SiC layer 43 is, for example, abut 1.1 μm.

More specifically, the trench gate structure is configured by the p-type base region 3, the n⁺-type source regions (n-type partial regions) 4, gate trenches 5, gate insulating films 6, and the gate electrodes 7. The p-type base region 3 is provided between the front surface of the semiconductor substrate 40 and the n-type drift region 2 and is in contact with the n-type drift region 2. The p-type base region 3 includes a lower portion (portion facing the n⁺-type drain region 1, hereinafter, p-type SiC portion (p-type silicon carbide portion)) 51 formed by the p-type SiC layer 43 and upper portions (hatched portion facing the source electrode 11, hereinafter, p-type polysilicon portion) 52 formed by a p-type polysilicon, adjacent to the p-type SiC portion 51 in a depth direction.

The p-type SiC portion 51 and the p-type polysilicon portions 52 are adjacent to the gate trenches 5 and in contact with the gate insulating films 6 at sidewalls of the gate trenches 5. Channels are formed in portions of the p-type SiC portion 51 and the p-type polysilicon portions 52 along the sidewalls of the gate trenches 5. A portion of the p-type SiC layer 43 excluding the n⁺-type source regions 4, formation regions (portions removed in forming later-described trenches 53) of the p-type polysilicon portions 52, and portions removed in forming the gate trenches 5 constitutes the p-type SiC portion 51.

The p-type polysilicon portions 52 are formed by embedding the p-type polysilicon doped with a p-type dopant in the trenches 53 formed in the p-type SiC layer 43 or by ion-implanting a p-type dopant in a non-doped polysilicon embedded in the trenches 53. As the p-type dopant for forming the p-type polysilicon portions 52, for example, Al or B may be used. Each of the p-type polysilicon portions 52 has a lower surface (surface facing the n⁺-type drain region 1) in contact with the p-type SiC portion 51. The trenches 53 are formed to a depth so as to not penetrate through the p-type SiC portion 51 (the p-type SiC layer 43) in the depth direction.

A dosage of the p-type dopant introduced into the p-type polysilicon portions 52 is substantially a same dosage as the dosage of the p-type dopant introduced into the p-type SiC portion 51. The band gap of polysilicon is smaller than the band gap of SiC and thus, the sheet resistance of the p-type polysilicon portions 52 is independent of the temperature of the semiconductor substrate 40 and nearly constant without fluctuation even when the junction temperature (the temperature of the semiconductor substrate 40) becomes a low temperature of about-40 degrees C. or about-55 degrees C. or when the junction temperature becomes a high temperature (about 175 degrees C. or greater). The sheet resistance of the p-type polysilicon portions 52 exhibits a similar tendency with respect to the temperature of the semiconductor substrate 40 as the n⁺-type region in FIG. 7.

Thus, the carrier concentration of the p-type polysilicon portions 52 is nearly independent of the temperature of the semiconductor substrate 40 and even when the temperature of the semiconductor substrate 40 is a low temperature, majority carriers (holes) in the p-type polysilicon portions 52 are abundant. Thus, when the MOSFET (the semiconductor device 10) turns off and dV/dt changes steeply, the majority carriers in the p-type base region 3 are not depleted and spreading of a depletion layer in the p-type base region 3 is difficult. The p-type polysilicon portions 52 function as a stopper that stops a depletion layer from reaching the n⁺-type source regions 4, said depletion layer spreading from the pn junctions between the p-type base region 3 (the p-type SiC portion 51) and the n-type drift region 2 when the MOSFET is off.

The p-type polysilicon portions 52 face lower surfaces of all the n⁺-type source regions 4. Provided the stopper function of the p-type polysilicon portions 52 is obtained, the p-type polysilicon portions 52 may reach the front surface of the semiconductor substrate 40, may be disposed apart from the front surface of the semiconductor substrate 40, and/or may be positioned closer to the n⁺-type drain region 1 than are the lower surfaces of the n⁺-type source regions 4. In an instance in which the p-type polysilicon portions 52 are apart from the front surface of the semiconductor substrate 40, the p-type SiC portion 51 is between the front surface of the semiconductor substrate 40 and the p-type polysilicon portions 52.

The p-type polysilicon portions 52 may be disposed apart from the front surface of the semiconductor substrate 40 and thus, contact trenches 8 of the source electrode 11 may be provided at the front surface of the semiconductor substrate 40 (refer to FIG. 3). In this instance, the p-type polysilicon portions 52 reach deep positions closer to the n⁺-type drain region 1 than are bottoms of the contact trenches 8; the contact trenches 8 are provided completely in the p-type polysilicon portions 52; and the p-type polysilicon portions 52 are exposed at inner walls of the contact trenches 8. A p⁺⁺-type contact region (not depicted) may be provided between each of the bottoms of the contact trenches 8 and a corresponding one of the p-type polysilicon portions 52.

From the front surface of the semiconductor substrate 40, a depth position of a bottom of each of the p-type polysilicon portions 52, preferably, may be equivalent to two times a thickness of the n⁺-type source regions 4 or more preferably, may be equivalent to three times the thickness of the n⁺-type source regions 4. The thickness of the n⁺-type source regions 4 is a depth from the front surface of the semiconductor substrate 40 to the lower surfaces of the n⁺-type source regions 4. Activation of the p-type dopant in the p-type polysilicon portions 52 and other later-described p-type polysilicon portions may be performed concurrently with the activation of the dopants in the SiC layers 42, 43 by laser annealing from the front surface of the semiconductor substrate 40 or a general heat treatment such as furnace annealing.

The p-type polysilicon portions 52 may be formed in multiple stages. In other words, the p-type SiC layer 43 may be divided into multiple sublayers and at each stage of epitaxial growth of a sublayer, formation of the trenches 53 and embedding of the p-type polysilicon portions 52 may be performed. For example, in an instance in which the p-type polysilicon portions 52 reach the front surface of the semiconductor substrate 40, the p-type SiC layer 43 is divided into two sublayers and grown by epitaxy. In a first sublayer of the p-type SiC layer 43, the trenches 53 (53a) are formed to a predetermined depth, lower portions of the p-type polysilicon portions 52 are embedded in the trenches 53a.

In a second sublayer of the p-type SiC layer 43, the trenches 53 (53b) are formed to a depth reaching the lower portions of the p-type polysilicon portions 52, upper portions of the p-type polysilicon portions 52 are embedded in the trenches 53b, and each of the upper portions is connected to a corresponding one of the lower portions, thereby forming the p-type polysilicon portions 52. The lower portions of the p-type polysilicon portions 52, for example, are portions closer to the n⁺-type drain region 1 than are the n⁺-type source regions 4. The upper portions of the p-type polysilicon portions 52, for example, are portions adjacent to the n⁺-type source regions 4 in a direction parallel to the front surface of the semiconductor substrate 40.

In this instance, in the first sublayer of the p-type SiC layer 43, portions remaining after formation of the trenches 53a constitute the p-type SiC portion 51. In the second sublayer of the p-type SiC layer 43, each of the n⁺-type source regions 4 is formed so as to be between any one of the p-type polysilicon portions 52 (the trenches 53b) and an adjacent one of the gate trenches 5. The n⁺-type source regions 4 are diffused regions formed by ion implantation in surface regions of the p-type SiC layer 43. The n⁺-type source regions 4 are selectively provided between the front surface of the semiconductor substrate 40 and the p-type base region 3, the n⁺-type source regions 4 being in contact with the p-type base region 3.

The n⁺-type source regions 4 are in contact with ohmic electrodes 17 at the front surface of the semiconductor substrate 40. The n⁺-type source regions 4 are adjacent to the sidewalls of the gate trenches 5 and are in contact with the gate insulating films 6 at the sidewalls of the gate trenches 5. For example, in an instance in which the gate trenches 5 extend linearly in a direction parallel to the front surface of the semiconductor substrate 40, the p-type SiC portion 51, the p-type polysilicon portions 52, and the n⁺-type source regions 4 extend linearly in a longitudinal direction of the gate trenches 5. The n⁺-type source regions 4 may be scattered in the longitudinal direction of the gate trenches 5.

Further, in an instance in which the n⁺-type source regions 4 are scattered in the longitudinal direction of the gate trenches 5, the n⁺-type source regions 4 and the p-type base region 3 (or the p⁺⁺-type contact regions, which are electrical contacts for the later-described ohmic electrodes 17) are disposed adjacently and repeatedly alternate with one another in the longitudinal direction of the gate trenches 5. In the instance in which the n⁺-type source regions 4 are scattered in the longitudinal direction of the gate trenches 5, any two of the n⁺-type source regions 4, respectively, adjacent to the sidewalls of any one of the gate trenches 5 may or may not face each other in a lateral direction of the gate trenches 5.

The n⁺-type source regions 4 may be disposed between the boundary region 32 and an outermost one of the gate trenches 5, the outermost one being closest to the chip end, among the gate trenches 5. The p⁺⁺-type contact regions (not depicted) that are electrical contacts for the ohmic electrodes 17 may be provided between the front surface of the semiconductor substrate 40 and the p-type base region 3. The p⁺⁺-type contact regions may be diffused regions formed by ion implantation in surface regions of the p-type SiC layer 43 or may be formed by increasing the doping concentration in regions of the p-type polysilicon portions 52.

For example, P, As, or nitrogen (N) may be used as an n-type dopant for forming an n-type region (an n⁺-type stopper channel region) in a region other than in the later-described operating region of the active region 31, and the n⁺-type source regions 4. For example, Al or B may be used as a p-type dopant for forming the p-type SiC portion and the p-type polysilicon portion constituting a p-type region (the p-type outer peripheral region, p-type regions configuring the voltage withstanding structure) in a region other than the later-described operating region of the active region 31, and the p⁺⁺-type contact regions.

The gate trenches 5 penetrate through the n⁺-type source regions 4, the p-type polysilicon portions 52, and the p-type SiC portion 51 in the depth direction from the front surface of the semiconductor substrate 40 and terminate in the n-type SiC layer 42. The gate trenches 5, for example, extend linearly in a direction (longitudinal direction, direction of view in FIG. 2) parallel to the front surface of the semiconductor substrate 40, and are disposed adjacent to one another in a lateral direction (direction orthogonal to the longitudinal direction, horizontal direction in FIG. 2), in a striped pattern. The gate electrodes 7 are provided in the gate trenches 5 via the gate insulating films 6.

Between the p-type base region 3 and the n-type drift region 2, the p⁺-type regions 21 are provided facing the bottoms of the gate trenches 5, at deep positions closer to the n⁺-type drain region 1 than are the bottoms of the gate trenches 5. The p⁺-type regions 21 are connected to the p⁺-type connecting portions 22 by the p-type base region 3 and are fixed to the potential of the source electrode 11. The p⁺-type regions 21 may be in contact with the gate insulating films 6 at the bottoms of the gate trenches 5. The p⁺-type regions 21 deplete when the MOSFET is off and have a function of mitigating electric field near the bottoms of the gate trenches 5.

A width (width in the lateral direction) of each of the p⁺-type regions 21, for example, is greater than a width (width in the lateral direction) of each of the gate trenches 5. The p⁺-type connecting portions 22 are along the sidewalls of the gate trenches 5 and reach the p-type base region 3, from the p⁺-type regions 21. The p⁺-type connecting portions 22 may be scattered in the longitudinal direction of the gate trenches 5 or each may extend linearly in the longitudinal direction of the gate trenches 5, along only one of the sidewalls of a corresponding one of the gate trenches 5. The p⁺-type regions 21 and the p⁺-type connecting portions 22 are diffused regions formed by ion implantation in the n-type SiC layer 42.

Between the p-type base region 3 and the n-type drift region 2, an n-type current spreading region (not depicted) may be provided at a deep position closer to the n⁺-type drain region 1 than are the bottoms of the gate trenches 5; the n-type current spreading region may be in contact with the p-type base region 3, the n-type drift region 2, the p⁺-type regions 21, and the p⁺-type connecting portions 22. The n-type current spreading region is a so-called current spreading layer (CSL) that reduces carrier spreading resistance. The n-type current spreading region is a diffused region formed by ion-implantation in the n-type SiC layer 42.

A portion of the n-type SiC layer 42 excluding the p⁺-type regions 21, the p⁺-type connecting portions 22, the n-type current spreading region, the later-described p-type outer peripheral region (not depicted) of the non-operating region of the active region 31 and the boundary region 32, the p-type regions (not depicted) configuring the later-described voltage withstanding structure of the edge termination region 33, and a later-described channel stopper region (not depicted) constitutes the n⁻-type drift region 2. For example, in the edge termination region 33, the p-type SiC layer 43 is removed, whereby the n-type SiC layer 42 constitutes the front surface of the semiconductor substrate 40 in the edge termination region 33.

The p-type outer peripheral region (third p-type region) is provided in contact with the n-type drift region 2, in an entire region between the front surface of the semiconductor substrate 40 and the n-type drift region 2 in the boundary region 32. The p-type outer peripheral region surrounds the periphery of the active region 31 and extends in an entire area between the n-type drift region 2 and the front surface of the semiconductor substrate 40 in the non-operating region of the active region 31. The p-type outer peripheral region is fixed to the potential of the source electrode 11 and has a function of drawing out holes in the n-type drift region 2 in the edge termination region 33, to the source electrode 11 or the source ring 16, when the MOSFET is off.

The p-type regions configuring the voltage withstanding structure (second p-type region) are selectively provided in the edge termination region 33, between the front surface of the semiconductor substrate 40 and the n-type drift region 2; the p⁻-type regions surround the periphery of the active region 31 in concentric shapes. As the voltage withstanding structure, for example, a junction termination extension (JTE) structure or a field limiting ring (FLR) constituted by a floating p-type region may be disposed.

A JTE structure is a structure in which multiple p-type regions of differing doping concentrations are disposed adjacent to one another in concentric shapes surrounding the periphery of the active region 31, the p-type regions being disposed in descending order of doping concentration in a direction from the chip center to the chip end. The channel stopper region is provided closer to the chip end than is the voltage withstanding structure; the channel stopper region is provided between the front surface of the semiconductor substrate 40 and the n⁻-type drift region 2; the channel stopper region is apart from the voltage withstanding structure and exposed at the chip end (side surface of the semiconductor substrate 40). The channel stopper region may be an n⁺-type or may be a p⁺-type (second p-type region).

Preferably, these p-type regions provided in a region other than the operating region of the active region 31 may have a structure in which, similar to the p-type base region 3, a p-type SiC portion and a p-type polysilicon portion are adjacent to each other in the depth direction. The p-type polysilicon portion of these p-type regions, similar to the p-type polysilicon portions 52 of the p-type base region 3, are formed by embedding a p-type polysilicon layer in trenches of a predetermined depth formed in the semiconductor substrate 40. The p-type outer peripheral region of the boundary region 32, for example, may have a stacked structure constituted by p-type portions formed concurrently with the p⁺-type regions 21, the p⁺-type connecting portions 22, the p-type SiC portion 51 and the p-type polysilicon portions 52.

An interlayer insulating film 9 is provided in nearly an entire area of the front surface of the semiconductor substrate 40 and covers all the gate electrodes 7. The ohmic electrodes 17 are in ohmic contact with the semiconductor substrate 40 in contact holes of the interlayer insulating film 9 and are electrically connected to the p-type base region 3 and the n⁺-type source regions 4 (and the p⁺⁺-type contact regions in an instance in which the p⁺⁺-type contact regions are provided). The ohmic electrodes 17 are constituted by, for example, a nickel silicide (NixSiy, where, x, y are positive numbers) film formed by silicide conversion of the semiconductor substrate 40.

A barrier metal 18 covers substantially an entire area of the surfaces of the ohmic electrodes 17 and the interlayer insulating film 9 in the active region 31. The barrier metal 18 has a function of preventing atomic diffusion and reactions between the source electrode 11 and the semiconductor substrate 40. The source electrode 11 is provided in nearly an entire area of the front surface of the semiconductor substrate 40 in the operating region of the active region 31; the source electrode 11 being electrically connected to the p-type base region 3 and the n⁺-type source regions 4 (and the p⁺⁺-type contact regions in an instance in which the p⁺⁺-type contact regions are provide), via the barrier metal 18 and the ohmic electrodes 17.

The contact trenches 8 may be provided at the front surface of the semiconductor substrate 40 (refer to FIG. 3). In this instance, the n⁺-type source regions 4 and the p-type polysilicon portions 52 are exposed at the inner walls of the contact trenches 8. The p⁺⁺-type contact regions may be provided between the bottoms of the contact trenches 8 and the p-type polysilicon portions 52. The barrier metal 18 and the ohmic electrodes 17 are provided along the inner walls of the contact trenches 8, the source electrode 11 being provided on the barrier metal 18 so as to be embedded in the contact trenches 8.

A portion of the source electrode 11 exposed in an opening of a passivation film (not depicted) functions as the source pad. The passivation film covers an uppermost surface of the front surface of the semiconductor substrate 40 and is a surface protecting film that protects the front surface of the semiconductor substrate 40. A drain electrode (second electrode) 19 is provided in an entire area of the back surface (back surface of the n⁺-type starting substrate 41) of the semiconductor substrate 40. The drain electrode 19 is in ohmic contact with the back surface of the semiconductor substrate 40 and is electrically connected to the n⁺-type drain region 1 (the n⁺-type starting substrate 41).

An entire area of the front surface of the semiconductor substrate 40 in the non-operating region of the active region 31, the boundary region 32, and the edge termination region 33 is covered by an insulating layer in which a field oxide film (not depicted) and the interlayer insulating film 9 are stacked sequentially in the order stated. The p-type outer peripheral region and the p⁻-type regions configuring the voltage withstanding structure are covered by the insulating layer. The gate polysilicon wiring layer and the gate resistor 14 (refer to FIG. 1) directly beneath the gate pad 12, the gate runner 13, and the gate ring 15 (refer to FIG. 1) are provided between the field oxide film and the interlayer insulating film 9.

Surfaces of the gate pad 12, the gate runner 13, the gate ring 15, the gate polysilicon wiring layer directly beneath (beneath the gate pad 12, the gate runner 13, and the gate ring 15), the gate resistor 14 (refer to FIG. 1) all face the p-type outer peripheral region via the field oxide film. The source ring 16 electrically connected to the p-type outer peripheral region, via contact holes of the interlayer insulating film 9 and the field oxide film. The gate pad 12, the gate runner 13, the gate ring 15, and the source ring 16, for example, are formed concurrently with the source electrode 11 and are provided at a same level as the source electrode 11.

Operation of the semiconductor device 10 according to the first embodiment (MOSFET) is described. When voltage that is positive with respect to the source electrode 11 is applied to the drain electrode 19 and a voltage at least equal to a gate threshold voltage is applied to the gate electrodes 7, in portions of the p-type SiC portion 51 and the p-type polysilicon portions 52 of the p-type base region 3 between the n-type drift region 2 and the n⁺-type source regions 4, channels (n-type inversion layer) are formed along the sidewalls of the gate trenches 5. As a result, a drift current (main current) flows from the n⁺-type drain region 1, through the n-type drift region 2 and the channels, to the n⁺-type source regions 4, and the MOSFET turns on.

On the other hand, when voltage that is positive with respect to the source electrode 11 is applied to the drain electrode 19 and a voltage applied to the gate electrodes 7 is less than the gate threshold voltage, pn junctions (main junctions) between the p-type base region 3, the p⁺-type regions 21, the p⁺-type connecting portions 22, and the n-type drift region 2 are reverse biased, whereby the MOSFET maintains an off state. A depletion layer spreads in the active region 31, from the pn junctions, in directions to both main surfaces of the semiconductor substrate 40; and a depletion layer spreads in a horizontal direction, from the operating region of the active region 31 to the non-operating region of the active region 31 and the boundary region 32. The n-type drift region 2 in the operating region of the active region 31 is depleted, whereby a predetermined breakdown voltage of the operating region of the active region 31 is ensured.

Further, in the non-operating region of the active region 31 and the boundary region 32, pn junctions between the p-type outer peripheral region and the n-type drift region 2 are reverse biased, whereby a depletion layer spreads in the n-type drift region 2, in a horizontal direction from the non-operating region of the active region 31 and the boundary region 32 to the edge termination region 33. Further, in the edge termination region 33, pn junctions between the p-type regions configuring the voltage withstanding structure and the n-type drift region 2 are reverse biased, whereby a depletion layer spreads in the n-type drift region 2 in the edge termination region 33, in a horizontal direction toward the chip end. A predetermined breakdown voltage of the edge termination region 33 based on a dielectric breakdown field strength of the semiconductor material is ensured to the extent that the depletion layer extends to the chip end in the n-type drift region 2 in the edge termination region 33.

Further, during a period in which the MOSFET transitions from on to off, parasitic pn junction diodes (body diodes) formed by pn junctions between the p-type base region 3, the p⁺-type regions 21, the p⁺-type connecting portions 22, the p-type outer peripheral region, and the n-type drift region 2 conduct in the forward direction; and carriers (holes and electrons) are injected into and accumulate in the n-type drift region 2. When the MOSFET turns off from this state (reverse recovery of the body diodes), holes in the n-type drift region 2 pass through the p-type base region 3 of the active region 31 or the p-type outer peripheral region of the boundary region 32 and are discharged out to the source electrode 11 or the source ring 16, and electrons in the n-type drift region 2 are discharged out to the drain electrode 19, whereby the MOSFET turns off.

When the MOSFET is off, the higher is the voltage applied to the pn junctions between the p-type base region 3 and the n-type drift region 2, the closer the depletion layer reaches the depth positions dₚₓ, dₙₓ, which are away from a depth position do of the pn junctions. The operating region of the active region 31 is designed so that the depletion layer that spreads vertically from the pn junctions between the p-type base region 3 and the n-type drift region 2 when the MOSFET is off does not reach the n⁺-type source regions 4. Further, as described above, the sheet resistance of the p-type polysilicon portions 52 configuring the p-type base region 3 is independent of the temperature of the semiconductor substrate and thus, even when the temperature of the semiconductor substrate, for example, is a low temperature of about-40 degrees C. or about-55 degrees C., the carrier concentration of the p-type polysilicon portions 52 does not change. Thus, when the MOSFET is off, independent of the temperature of the semiconductor substrate, the depletion layer does not easily spread in the p-type polysilicon portions 52 of the p-type base region 3 and the MOSFET is turned off rapidly, whereby even when dV/dt changes steeply, the depletion layer does not reach the n⁺-type source regions 4.

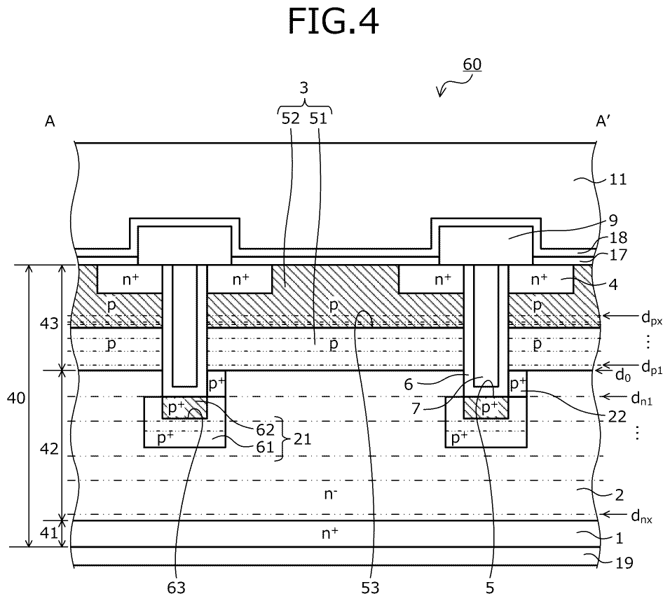

In FIGS. 2 and 3, short-dash two-dot chains and long-dash two-dot chains conceptually represent the depth positions dₚₓ, dₙₓ (where, “x” is greater than or equal to 1: in other words, equipotential line distribution of the depletion layer in the p-type base region 3 and the n-type drift region 2) corresponding to the diffusion potential of both ends (end in the p-type base region 3 and end in the n-type drift region 2) of the depletion layer that spreads vertically from the pn junctions between the p-type base region 3 and the n-type drift region 2, when the MOSFET is off (similarly in FIGS. 4 to 6). FIGS. 2 and 3 depict an example in which an interval (potential difference between dash two-dot chains) of equipotential lines of the depletion layer in the p-type base region 3 and in the n⁻-type drift region 2 is assumed to be, for example, 100V and an end (a sixth depth position dₚ₆ from the depth position do of the pn junctions) of the depletion layer does not reach the n⁺-type source regions 4, even when the voltage applied to the pn junctions between the p-type base region 3 and the n-type drift region 2 is about 600V (similarly in FIGS. 4 to 6).

The p-type regions (the p-type outer peripheral region, the p-type regions configuring the voltage withstanding structure, the p⁺-type channel stopper region) provided between the front surface of the semiconductor substrate 40 and the n-type drift region 2 in the non-operating region of the active region 31, the boundary region 32, and the edge termination region 33 also include the p-type polysilicon portion and thus, even when the temperature of the semiconductor substrate 40 is a low temperature, spreading of the depletion layer in the p-type regions in a vertical direction is inhibited. As a result, even when the dV/dt changes steeply when the SiC-MOSFET turns off, the depletion layer that spreads in the p-type regions does not reach the insulating layer on the front surface of the semiconductor substrate 40 and thus, dielectric breakdown due to electric field concentration may be suppressed. As described, by including the p-type polysilicon portion in any of the p-type regions in the semiconductor substrate 40, spreading of the depletion layer in a vertical direction may be suppressed nearly as designed, independent of the temperature of the semiconductor substrate 40.

Even when the MOSFET is off and the depletion layer that spreads in the p-type base region 3 from the pn junctions between the p-type base region 3 and the n-type drift region 2 reaches the p⁺⁺-type contact regions, no problem occurs. Further, when the MOSFET is off, the n-type doping concentration of the n-type drift region 2 is lower than the p-type doping concentration of the p-type base region 3, whereby the depletion layer that spreads from the pn junctions between the p-type base region 3 and the n-type drift region 2 spreads vertically in the n-type drift region 2 sooner than the depletion layer spreads vertically in the p-type base region 3. The sooner the depletion layer spreads vertically in the n-type drift region 2, the greater the electric field applied to the n-type drift region 2 may be reduced. Even when the depletion layer quickly spreads vertically in the n-type drift region, the n⁺-type drain region 1 is present between the back surface of the semiconductor substrate 40 and the n-type drift region 2 and thus, no problem occurs.

In any of the n-type SiC regions (the n-type drift region 2, the n⁺-type source regions 4, the n-type current spreading region, the n⁺-type stopper channel region) in the semiconductor substrate 40 as well, the sheet resistance of the n-type SiC regions is presumed to exhibit the same tendency as the tendency of the n⁺-type region (corresponds to the n⁺-type source regions 104 of the reference structure depicted in FIG. 8) in FIG. 7 with respect to the temperature of the semiconductor substrate 40, independent of the doping concentration. While not depicted, the present inventor confirmed that the sheet resistance of a Si region with silicon (Si) as a semiconductor material exhibits the same tendency as the tendency of the n⁺-type region in FIG. 7 with respect to the temperature of the semiconductor substrate 40, independent of the conductivity type.

As described, according to the first embodiment, the p-type regions provided in the operating region of the active region are configured by the p-type SiC portion and the p-type polysilicon portion. The sheet resistance of the p-type polysilicon portion is nearly constant independent of the temperature of the semiconductor substrate and thus, even when the temperature of the semiconductor substrate is a low temperature, the carrier concentration of the p-type polysilicon portion does not decrease and majority carriers (holes) in the p-type polysilicon portion are abundant. For example, in the MOSFET, under a condition that the temperature of the semiconductor substrate is a low temperature, even when the MOSFET is turned off rapidly and dV/dt changes steeply, spreading of the depletion layer in the p-type base region is difficult and majority carriers in the p-type base region are not depleted. Thus, the depletion layer may be suppressed from reaching the n⁺-type source regions and punching through.

As a result, switching capability of the MOSFET (semiconductor device) during switching, particularly, tolerance against steep dV/dt may be enhanced, and variation of electrical characteristics of the MOSFET under the condition that the temperature of the semiconductor substrate becomes a low temperature may be suppressed. For example, the inventor confirmed experimentally that even in an instance in which the temperature of the semiconductor substrate is a low temperature of about-40 degrees C. or about-55 degrees C., switching capability enabling blocking of hole current (reverse recovery current of the body diodes) that is about five times the rated current or greater is obtained with respect to a steep dV/dt of about 50 kV/second or about 100 kV/second. Further, even when the temperature of the semiconductor substrate is a high temperature of about 175 degrees C. or about 200 degrees, similar to an instance in which the temperature of the semiconductor substrate is a low temperature, switching capability with respect to a steep dV/dt may be obtained.

Further, according to the first embodiment, a portion of each of the p-type regions (p-type regions in the non-operating region of the active region, the p-type outer peripheral region of the boundary region, and in the edge termination region, the p-type regions configuring the voltage withstanding structure and the p⁺-type channel stopper region) provided in a region other than the operating region of the active region is a p-type polysilicon portion, whereby the p-type polysilicon portion may be caused to function as a stopper that suppresses spreading of the depletion layer. Thus, in regions other than the operating region of the active region, instances of the depletion layer reaching the insulating layer on the front surface of the semiconductor substrate and electric field concentration at this location may be suppressed. Further, the depletion layer may be suppressed from reaching the chip ends in a horizontal direction and punching through. As a result, the switching capability of the MOSFET may be further enhanced.

A semiconductor device according to a second embodiment solving the problems above is described. FIG. 4 is a cross-sectional view depicting a structure of a semiconductor device according to the second embodiment. A layout when a semiconductor device 60 according to the second embodiment is viewed from the front surface of the semiconductor substrate 40 is the same as the layout depicted in FIG. 1 with an exception of reference numeral “10” being replaced with reference numeral “60”. FIG. 4 depicts a cross-section of the structure along cutting line A-A′ in FIG. 1. The semiconductor device 60 according to the second embodiment differs from the semiconductor device 10 according to the first embodiment (refer to FIG. 2) in that each of the p⁺-type regions 21 for mitigating electric field is configured by a p⁺-type SiC portion (p-type silicon carbide portion) 61 and a p⁺-type polysilicon portion 62 (hatched portion).

The p⁺-type SiC portions 61 are diffused regions formed by ion-implantation in the n-type SiC layer 42. The p⁺-type polysilicon portions 62 are provided between the bottoms of the gate trenches 5 and the p⁺-type SiC portions 61. The p⁺-type polysilicon portions 62 are formed by embedding a p⁺-type polysilicon doped with a p-type dopant in trenches 63 formed, respectively, in the p⁺-type SiC portions 61 or the p⁺-type polysilicon portions 62 are formed by ion-implanting a p-type dopant in a doped polysilicon embedded in the trenches 63. Each of the p⁺-type polysilicon portions 62 is in contact with a corresponding one of the p⁺-type SiC portions 61 along the entire inner wall of a corresponding one of the trenches 63. The trenches 63 are formed in the depth direction, from upper surfaces of the p⁺-type SiC portions 61 to a depth so as to terminate in the p⁺-type SiC portions 61.

The p⁺-type polysilicon portions 62 are formed by a polysilicon similar to the p-type polysilicon portions 52 and thus, the carrier concentration is nearly independent of the temperature of the semiconductor substrate. Even when the temperature of the semiconductor substrate is a low temperature, majority carriers are abundant in the p⁺-type polysilicon portions 62. The p⁺-type polysilicon portions 62 suppress complete depletion of the p⁺-type regions 21 by a depletion layer that spreads in the p⁺-type regions 21, from the pn junctions between the p⁺-type regions 21 and the n-type drift region 2 when the MOSFET (the semiconductor device 60) is off; the p⁺-type polysilicon portions 62 function as a stopper that stops the depletion layer from reaching the gate insulating films 6. As a p-type dopant for forming the p⁺-type SiC portions 61 and the p⁺-type polysilicon portions 62, for example, Al or B may be used.

Dosage of the p-type dopant introduced into the p⁺-type polysilicon portions 62 is substantially a same as a dosage of the p-type dopant introduced into the p⁺-type SiC portions 61. Activation of the p-type dopant in the p⁺-type polysilicon portions 62 may be performed concurrently with the activation of the dopants in the SiC layers 42, 43 by a general heat treatment such as furnace annealing or laser annealing from the front surface of the semiconductor substrate 40. The p⁺-type polysilicon portions 62 may be in contact with the gate insulating films 6, the p⁺-type connecting portions 22, and the n-type drift region 2. A width (width in the lateral direction) of each of the p⁺-type polysilicon portions 62 may be, for example, equal to or greater than a width (width in the lateral direction) of each of the gate trenches 5.

Similar to the contact trenches 8 of the other example of the semiconductor device 10 according to the first embodiment depicted in FIG. 3 described above, contact trenches may be provided in the semiconductor device 60 according to the second embodiment.

As described, according to the second embodiment, an effect similar to an effect of the first embodiment may be obtained. Further, according to the second embodiment, in the p⁺-type regions, a depletion layer spreads from the pn junctions between the p⁺-type regions for mitigating electric field and the n⁻-type drift region when the MOSFET is off and the p⁺-type polysilicon portions in the p⁺-type regions for mitigating electric field make it difficult for the depletion layer to extend to the gate trenches and thus, the effect of mitigating electric field near the bottoms of the gate trenches may be enhanced.

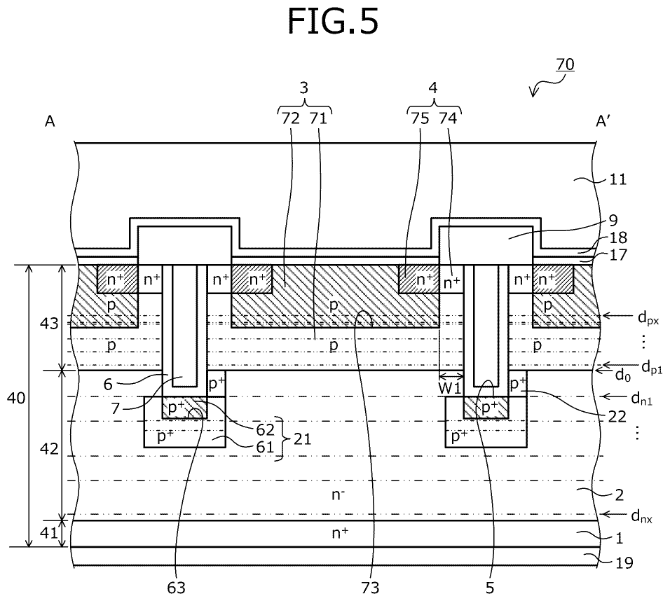

A semiconductor device according to a third embodiment that solves the problems above is described. FIG. 5 is a cross-sectional view depicting a structure of a semiconductor device according to the third embodiment. A layout when a semiconductor device 70 according to the third embodiment is viewed from the front surface of the semiconductor substrate 40 is the same as the layout depicted in FIG. 1 with an exception of reference numeral “10” being replaced with reference numeral “70”. FIG. 5 depicts a cross-section of the structure along cutting line A-A′ in FIG. 1. The semiconductor device 70 according to the third embodiment differs from the semiconductor device 10 according to the first embodiment (refer to FIG. 2) in that portions of the p-type base region 3 where the channels are formed are configured by only a p-type SiC portion 71.

In the third embodiment, of the p-type SiC portion 71 and p-type polysilicon portions (hatched portions) 72 configuring the p-type base region 3, only the p-type SiC portion 71 is disposed adjacent to the gate trenches 5 and is in contact with the gate insulating films 6 at the sidewalls of the gate trenches 5. The p-type polysilicon portions 72 are formed by embedding a p⁺-type polysilicon doped with a p-type dopant in trenches 73 formed in the p-type SiC portion 71 or by ion-implanting a p-type dopant in a non-doped polysilicon embedded in the trenches 73.

The p-type polysilicon portions 72 are disposed between the front surface of the semiconductor substrate 40 and the p-type SiC portion 71 and are apart from the gate trenches 5. The trenches 73 are formed from the front surface of the semiconductor substrate 40 to a depth so as to not penetrate through the p-type SiC portion 71 (the p-type SiC layer 43) in the depth direction; the trenches 73 are apart from the gate trenches 5. A portion of the p-type SiC layer 43 excluding the n⁺-type source regions 4, formation regions (portions removed by the formation of the trenches 73) of the p-type polysilicon portions 72, and portions removed by the formation of the gate trenches 5 constitutes the p-type SiC portion 71.

In portions of the p-type base region 3 between the n-type drift region 2 and the n⁺-type source regions 4 (later-described n⁺-type SiC portions 74), where channels are formed, only the p-type SiC portion 71 is disposed. The p-type SiC portion 71 and the p-type polysilicon portions 72, excluding arrangement thereof, are similar, respectively, to the p-type SiC portion 51 and the p-type polysilicon portions 52 of the first embodiment. An interval W1 between any one of the p-type polysilicon portions 72 and an adjacent one of the gate trenches 5 is equivalent to a channel thickness in a direction orthogonal to the sidewalls of the gate trenches 5 and preferably, may be as narrow as possible.

When the temperature of the semiconductor substrate 40 is a low temperature, the carrier concentration of the p-type SiC portion 71 is lower than the carrier concentration of the p-type polysilicon portions 72 and thus, the depletion layer that spreads in the p-type base region 3 from the pn junctions between the p-type base region 3 and the n⁻-type drift region 2 when the MOSFET is off spreads more easily in the p-type SiC portion 71 than in the p-type polysilicon portions 72; the depletion layer curves along lower surface corners (each boundary between the lower surface and a side surface) of the p-type polysilicon portions 72 and protrudes in a long, thin state, the depletion layer extending between each of the p-type polysilicon portions 72 and an adjacent one of the gate trenches 5.

Preferably, the interval W1 between any one of the p-type polysilicon portions 72 and an adjacent one of the gate trenches 5 may be as narrow as possible so that the depletion layer, which extends between each of the p-type polysilicon portions 72 and an adjacent one of the gate trenches 5 in a direction to the n⁺-type source regions 4 (the n⁺-type SiC portions 74), is caused to spread in the p-type polysilicon portions 72 in a horizontal direction (the lateral direction of the gate trenches 5) and not reach the n⁺-type source regions 4. In particular, preferably, for example, the interval W1 between any one of the p-type polysilicon portions 72 and an adjacent one of the gate trenches 5 may be about 0.2 μm or less.

The n⁺-type source regions 4 may be formed by the n⁺-type SiC portions (n-type silicon carbide portions) 74 and n⁺-type polysilicon portions 75. The n⁺-type SiC portions 74 are diffused regions formed by ion-implantation in surface regions of the p-type SiC layer 43. The n⁺-type SiC portions 74 are selectively provided between the front surface of the semiconductor substrate 40 and the p-type SiC portion 71, the n⁺-type SiC portions 74 being in contact with the p-type SiC portion 71. The n⁺-type SiC portions 74 are adjacent to the gate trenches 5 and are in contact with the gate insulating films 6, at the sidewalls of the gate trenches 5. The n⁺-type SiC portions 74 may be in contact with the ohmic electrodes 17 or may be apart from the ohmic electrodes 17.

The n⁺-type polysilicon portions 75 are selectively provided between the front surface of the semiconductor substrate 40 and the p-type polysilicon portions 72; the n⁺-type polysilicon portions 75 are in contact with the p-type polysilicon portions 72. Each of the n⁺-type polysilicon portions 75 is provided adjacent to a corresponding one of the n⁺-type SiC portions 74 and faces a corresponding one of the gate trenches 5 with the corresponding one of the n⁺-type SiC portions 74 intervening therebetween. The n⁺-type polysilicon portions 75 are in contact with the ohmic electrodes 17, at the front surface of the semiconductor substrate 40. A depth of each of the n⁺-type polysilicon portions 75, for example, is substantially a same as a depth of each of the n⁺-type SiC portions 74.

The n⁺-type polysilicon portions 75 are formed by converting regions of each of the p-type polysilicon portions 72 into an n-type by ion-implantation of an n-type dopant. A dosage of the n-type dopant introduced into the n⁺-type polysilicon portions 75 is substantially a same as a dosage of the n-type dopant introduced into the n⁺-type SiC portions 74. Activation of the n-type dopant in the n⁺-type polysilicon portions 75 may be performed concurrently with the activation of the dopants in the SiC layers 42, 43 by a general heat treatment such as furnace annealing or laser annealing from the front surface of the semiconductor substrate 40.

The n⁺-type polysilicon portions 75, for example, are formed concurrently with the n⁺-type SiC portions 74. Excluding the portions constituting the n⁺-type polysilicon portions 75, the n⁺-type source regions 4 are similar to the n⁺-type source regions 4 of the first embodiment. The n⁺-type polysilicon portions 75 are indicated by hatching different from the hatching indicating the p-type polysilicon portions 72.

Contact trenches similar to the contact trenches 8 of the other example of the semiconductor device 10 according to the first embodiment depicted in FIG. 3 described above may be provided in the semiconductor device 70 according to the third embodiment. In this instance, the n⁺-type polysilicon portions 75 and the p-type polysilicon portions 72 are exposed at inner walls of the contact trenches. Here, while each of the p⁺-type regions 21 for mitigating electric field is configured by any one of the p⁺-type SiC portions 61 and a corresponding one of the p⁺-type polysilicon portions 62 similar to the second embodiment (refer to FIG. 4), each of the p⁺-type regions 21 for mitigating electric field may be configured by only a p⁺-type SiC portion similar to the p⁺-type regions 21 in the first embodiment.

As described, according to the third embodiment, even in an instance in which the p-type polysilicon portions of the p-type base region are disposed apart from the gate trenches or an instance in which a region of each of the n⁺-type source regions constitutes an n⁺-type polysilicon portion, effects similar to effects of the first and second embodiments may be obtained.

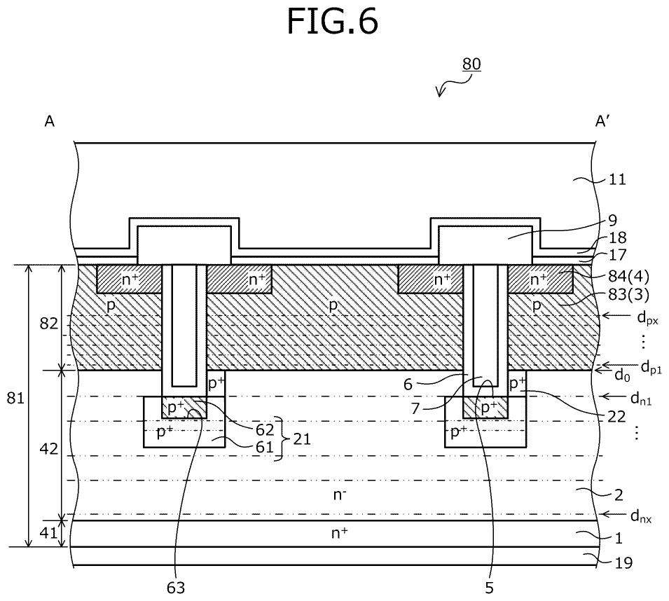

A semiconductor device according to a fourth embodiment that solves the problems above is described. FIG. 6 is a cross-sectional view depicting a structure of a semiconductor device according to the fourth embodiment. A layout when a semiconductor device 80 according to the fourth embodiment is viewed from a front surface of a semiconductor substrate 81 of the semiconductor device 80 is the same as the layout depicted in FIG. 1 with the exception of reference numerals “10” and “40” being replaced with reference numerals “80” and “81”, respectively. FIG. 6 depicts a cross-section of the structure along cutting line A-A′ in FIG. 1. The semiconductor device 80 according to the fourth embodiment differs from the semiconductor device 10 according to the first embodiment (refer to FIG. 2) in that the p-type base region 3 and the n⁺-type source regions 4 are configured only by a polysilicon (hatched portions).

In the fourth embodiment, the semiconductor substrate 81, for example, has a p-type polysilicon layer 82 constituting the p-type base region 3 instead of the p-type SiC layer 43 in the semiconductor substrate 40 in the first embodiment. The p-type polysilicon layer 82 may be formed by depositing a p-type polysilicon layer doped with a p-type dopant on the n⁻-type SiC layer 42 or may be formed by ion-implanting a p-type dopant in a non-doped polysilicon layer deposited on the n⁻-type SiC layer 42. Portions (p-type polysilicon portions) 83 of the p-type polysilicon layer 82 excluding n⁺-type polysilicon portions 84 constitute the p-type base region 3.

The n⁺-type polysilicon portions 84 constitute the n⁺-type source regions 4. The n⁺-type polysilicon portions 84 are formed by converting regions of the p-type polysilicon layer 82 into an n-type by ion-implantation of an n-type dopant. In the present embodiment, configuration is a same as the configuration in the first embodiment with the exception of all the n⁺-type source regions 4 being the n⁺-type polysilicon portions 84. Activation of the dopants in the p-type polysilicon portions 83 and the n⁺-type polysilicon portions 84 may be performed concurrently with the activation of the dopants in the SiC layer 42 by a general heat treatment such as furnace annealing or laser annealing from the front surface of the semiconductor substrate 81.

Contact trenches similar to the contact trenches 8 of the other example of the semiconductor device 10 according to the first embodiment depicted in FIG. 3 described above may be provided in the semiconductor device 80 according to the fourth embodiment. In this instance, the contact trenches are formed from the front surface of the semiconductor substrate 81 to a depth so as to not penetrate through the p-type polysilicon layer 82, and the n⁺-type polysilicon portions 84 and the p-type polysilicon portions 83 are exposed at inner walls of the contact trenches. Here, while each of the p⁺-type regions 21 for mitigating electric field is configured by any one of the p⁺-type SiC portions 61 and a corresponding one of the p⁺-type polysilicon portions 62 similar to the second embodiment (refer to FIG. 4), each of the p⁺-type regions 21 for mitigating electric field may be configured by only a p⁺-type SiC portion similar to the p⁺-type regions 21 in the first embodiment.

While effects based on physical properties of SiC decrease, the p⁺-type regions 21 may be configured by only the p⁺-type polysilicon portions 62. Further, p-type regions (p-type regions in the non-operating region of the active region 31, the p-type outer peripheral region of the boundary region 32, and in the edge termination region 33, the p-type regions configuring the voltage withstanding structure, and the p⁺-type channel stopper region) other than the p-type regions provided in the operating region of the active region 31 may also be configured by only p-type polysilicon portions. In the semiconductor devices 10, 60, 70 (refer to FIGS. 2 to 5) according to the first to third embodiments described above, the p-type regions provided in regions other than the operating region of the active region 31 and the p⁺-type regions 21 may be configured by only p-type polysilicon portions.

As described, according to the fourth embodiment, while effects based on physical properties of SiC decrease in an instance in which the p-type base region and the n⁺-type source regions are configured only by polysilicon, even in this instance, the switching capability of the MOSFET when the temperature of the semiconductor substrate is a low temperature may be obtained similarly to the first to third embodiments.

In the foregoing, the present disclosure is not limited to the described embodiments and various modifications within a range not departing from the spirit of the disclosure are possible. For example, in the described embodiments, instead of the trench gate structure in which the gate electrodes extend in the depth direction from the front surface of the semiconductor substrate, a planar structure in which flat plate-shaped gate electrodes extend along the front surface of the semiconductor substrate may be adopted. Further, the present disclosure is not limited to a MOSFET and is applicable to vertical semiconductor devices having pn junctions such as insulated gate bipolar transistors (IGBTs), bipolar junction transistors (BJTs), p-intrinsic-n (pin) diodes, and the like.

According to the described disclosure, even at low temperatures, the carrier concentration of the p-type polysilicon portion does not decrease and thus, the depletion layer does not easily spread in the p-type regions and thus, the majority carriers in the p-type regions are not depleted. As a result, the depletion layer does not easily reach a vicinity of the first main surface of the semiconductor substrate and local electric field concentration may be suppressed.

The semiconductor device of the present disclosure achieves an effect in that the switching capability may be enhanced.

As described above, the semiconductor device according to the present disclosure is useful for power semiconductor devices used in power converting equipment, power supply devices of various types of industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate containing silicon carbide, the semiconductor substrate having a first main surface and a second main surface opposite to each other;
an n-type region provided in the semiconductor substrate;
a p-type region provided in the semiconductor substrate, between the first main surface of the semiconductor substrate and n-type region, the p-type region being in contact with the n-type region;
a first electrode electrically connected to the p-type region; and
a second electrode electrically connected to the n-type region, wherein
at least one portion of the p-type region is a p-type polysilicon portion.

2. The semiconductor device according to claim 1, wherein a remaining portion of the p-type region excluding the p-type polysilicon portion is a p-type silicon carbide portion.

3. The semiconductor device according to claim 1, wherein the p-type region is entirely constituted by the p-type polysilicon portion.

4. The semiconductor device according to claim 1, further comprising a plurality of n-type partial regions selectively provided in the semiconductor substrate, between the first main surface of the semiconductor substrate and the p-type region, wherein
each of the plurality of n-type partial regions is entirely constituted by an n-type silicon carbide portion.

5. The semiconductor device according to claim 2, further comprising a plurality of n-type partial regions selectively provided in the semiconductor substrate, between the first main surface of the semiconductor substrate and the p-type region, wherein
each of the plurality of n-type partial regions is formed by an n-type polysilicon portion and an n-type silicon carbide portion that are mutually exclusive,
the n-type polysilicon portion is selectively provided in the p-type polysilicon portion, and
the n-type silicon carbide portion is selectively provided in the p-type silicon carbide portion.

6. The semiconductor device according to claim 3, further comprising a plurality of n-type partial regions selectively provided in the semiconductor substrate, between the first main surface of the semiconductor substrate and the p-type region, wherein
each of the plurality of n-type partial regions is entirely constituted by an n-type polysilicon portion.

7. The semiconductor device according to claim 1, wherein:
the semiconductor substrate has an active region; and
the semiconductor device further includes a predetermined device element structure provided in the active region, the predetermined device element structure having a pn junction between the p-type region and the n-type region, wherein
the first electrode is provided at the first main surface of the semiconductor substrate and is electrically connected to the device element structure, and
the second electrode is provided at the second main surface of the semiconductor substrate.

8. The semiconductor device according to claim 7, further comprising a termination region surrounding a periphery of the active region in a plan view of the semiconductor device, the termination region having a predetermined voltage withstanding structure disposed therein, wherein
the p-type region is one of a plurality of p-type regions provided in the semiconductor substrate,
the plurality of p-type regions further includes:
a first p-type region provided in the active region and configuring the device element structure, and
a second p-type region provided in the termination region and configuring the voltage withstanding structure.

9. The semiconductor device according to claim 8, further comprising:
a boundary region between the active region and the termination region; and
a wiring layer provided in the boundary region, on the first main surface of the semiconductor substrate via an insulating layer, wherein
the plurality of p-type regions further includes a third p-type region electrically connected to the first electrode, the third p-type region being provided in the boundary region and facing the wiring layer in a depth direction of the semiconductor device via the insulating layer.

10. The semiconductor device according to claim 1, wherein the p-type polysilicon portion has aluminum or boron as a p-type dopant therein.

11. The semiconductor device according to claim 5, wherein the n-type polysilicon portion has arsenic or nitrogen as an n-type dopant therein.

12. The semiconductor device according to claim 6, wherein the n-type polysilicon portion has arsenic or nitrogen as an n-type dopant therein.
